(19) United States
(12) Patent Application Publication
(10) Pub. No.: US 2016/0211124 A1
(43) Pub. Date: Jul. 21, 2016

(54) WARP CORRECTION METHOD FOR SPUTTERING TARGET WITH BACKING PLATE

(71) Applicant: TANAKA KIKINZOKU KOGYO K.K., Tokyo (JP)

(72) Inventors: Osamu ITOH, Tsukuba-shi, Ibaraki (JP); Takuya NAGASHIMA, Tsukuba-shi, Ibaraki (JP); Masahiro AONO, Tsukuba-shi, Ibaraki (JP); Takamichi YAMAMOTO, Tsukuba-shi, Ibaraki (JP)

(21) Appl. No.: 14/917,419

(22) PCT Filed: Sep. 5, 2014
(86) PCT No.: PCT/JP2014/073587

§ 371 Date: Mar. 8, 2016

(30) Foreign Application Priority Data
Sep. 12, 2013 (JP) 2013-189868

(51) Int. Cl. H01J 37/34; C23C 14/08; C23C 14/06; C23C 14/34

(52) U.S. Cl. CPC H01J 37/3423; C23C 14/3414; H01J 37/3429; C23C 14/08; C23C 14/0605

(57) ABSTRACT

Provided is a warp correction method which can correct warping in a warped sputtering target with a backing plate (BP) by a simple method. This warp correction method involves: an arrangement step of arranging a BP-attached sputtering target on a lower pressing surface of a pressing device in such a way that a target side located above, the pressing device including an upper pressing surface and the lower pressing surface opposing each other in a vertical direction, and of arranging a spacer between outer edge of the backing plate side of the BP-attached target and the lower pressing surface; and a pressing step of pressing the BP-attached target in the vertical direction by means of the pressing device after the arrangement step, wherein the target is a composite including at least one of metal oxide and carbon, the at least one of metal oxide and carbon being dispersed in a matrix metal.

### TECHNICAL FIELD

The present invention relates to a warp correction method for a sputtering target with a backing plate (hereinafter sometimes simply referred to as “warp correction method”), and particularly, to a warp correction method which can efficiently correct warping in a warped sputtering target with a backing plate (hereinafter sometimes referred to as “BP-attached target”).

### BACKGROUND ART

A sputtering target (hereinafter sometimes simply referred to as “target”) may be mounted to a sputtering device with a backing plate attached for mounting of the target to the sputtering device and cooling of the target during sputtering.

During attachment of the backing plate to the sputtering target, the sputtering target has been often bonded to the backing plate by heating the sputtering target and the backing plate to a temperature at which indium is molten (for example, about 250 to about 300° C.) to interpose molten indium between the sputtering target and the backing plate, and cooling the indium to normal temperature resulting in solidification as it is.

However, a difference in a thermal expansion coefficient between the sputtering target and the backing plate leads to different shrinkage amounts caused by cooling. Therefore, a BP-attached target in which the sputtering target is bonded to the backing plate may be warped when the target is cooled to normal temperature.

The warped BP-attached target is unlikely to be properly mounted to the sputtering device, and may not be properly cooled during sputtering.

As a technique of coping with these problems, techniques in which warping itself is not caused (for example, see Patent Literatures 1 and 2) and techniques of correcting warping (for example, see Patent Literatures 3, 4, and 5) are proposed.

However, in the technique described in Patent Literature 1, concave and convex portions to be tightly engaged with each other need to be formed on both bonding surfaces of the sputtering target and the backing plate to be bonded. This requires time and effort.

In the technique described in Patent Literature 2, a bonding region needs to be limited to an area other than a required portion of the center of a target member. This requires time and effort.

In the technique described in Patent Literature 3, correction needs to be performed under heating to a temperature that is 400° C. or higher and lower than the melting point of a brazing filler metal. This requires time and effort.

In the technique described in Patent Literature 4, vacuum suction is required. This requires time and effort.

In the technique described in Patent Literature 5, it is necessary that warping caused by cooling be intermittently measured and reverse warping offsetting the caused warping be applied each time. This requires time and effort.

### CITATION LIST

### Patent Literature

Patent Literature 1: Japanese Patent Application Laid-Open Publication No. Hei 8-188872
Patent Literature 2: Japanese Patent Application Laid-Open Publication No. Hei 6-65727
Patent Literature 3: Japanese Patent Application Laid-Open Publication No. Hei 5-214518

### Patent Literature 4: Japanese Patent Application Laid-Open Publication No. 2001-131738

### Patent Literature 5: Japanese Patent Application Laid-Open Publication No. 2001-140064

### SUMMARY OF INVENTION

### Technical Problem

The present invention has been made in view of the above-described problems. It is an object of the present invention to provide a warp correction method which can correct warping in a warped sputtering target with a backing plate by a simple method.

### Solution to Problem

The present inventor has intensively performed research and development to solve the above-described problems, and as a result, has found that the problems can be solved by the following warp correction method for a sputtering target with a backing plate. Thus, the present invention has been completed.

Namely, a warp correction method for a sputtering target with a backing plate according to the present invention is a warp correction method for a sputtering target with a backing plate, the method being for decreasing warping in the sputtering target with the backing plate, the sputtering target being bonded to the backing plate through a brazing filler metal, the sputtering target with the backing plate being warped convexly on the sputtering target side and being warped concavely on the backing plate side, the method comprising: an arrangement step of arranging the sputtering target with the backing plate on a lower pressing surface of a pressing device in such a way that the sputtering target side located above, the pressing device including an upper pressing surface and the lower pressing surface opposing each other in a vertical direction, the pressing device being capable of pressing a substance to be pressed arranged on the lower pressing surface in the vertical direction, and of arranging a spacer between outer edge of the backing plate side of the sputtering target with the backing plate and the lower pressing surface of the pressing device; and a pressing step of pressing the sputtering target with the backing plate in the vertical direction by means of the pressing device after the arrangement step, wherein the sputtering target is a composite including at least one of metal oxide and carbon, the at least one of metal oxide and carbon being dispersed in a matrix metal.

Herein, when a jig for compression is used during pressing the sputtering target with the backing plate, the jig also constitutes a part of the pressing device. For this reason, when the jig is used, the “upper pressing surface” of the pressing device corresponds to an upper pressing surface of the used jig, and the “lower pressing surface” of the pressing device corresponds to a lower pressing surface of the jig.

When the volume fraction of the total of the metal oxides and the carbon relative to the whole sputtering target is 10 to 60% by volume, the warp correction method can be suitably used.

For the backing plate, oxygen-free copper or a copper alloy can be used.

In the pressing step, a pressure to be applied to the sputtering target with the backing plate may be increased to a targeted pressure in a single step.

An amount of warping on the backing plate side of less than 0.1 mm can be achieved using the warp correction method.

The thickness of the spacer is preferably 0.05 to 0.5 mm.

As the brazing filler metal, indium can be suitably used.

As the brazing filler metal, an Sn-based alloy can also be used. Herein, the Sn-based alloy represents an alloy containing Sn, and is a concept including not only a binary system Sn alloy but also a ternary or higher system Sn alloy.

In the arrangement step, it is preferable that a buffer material be disposed between an outside surface on the sputtering target side of the sputtering target with the backing plate and the upper pressing surface.

As the buffer material, for example, silicon rubber can be used. The silicon rubber preferably has a thickness of 0.5 to 1.5 mm.

The warp correction method for a sputtering target with a backing plate according to the present invention can be performed at normal temperature in the air.

Further, the warp correction method for a sputtering target with a backing plate according to the present invention may be performed so that the sputtering target and the backing plate are not plastically deformed.

### Advantageous Effects of Invention

According to the present invention, warping in a warped sputtering target with a backing plate can be corrected by a simple method, and the production efficiency of a sputtering target with a backing plate can be improved.

### BRIEF DESCRIPTION OF DRAWINGS

FIG. 1 is a side view schematically illustrating a warped BP-attached target.

FIG. 2 is a side view schematically illustrating a state where a warped BP-attached target is set in a pressing device when a warp correction method of the present embodiment is implemented.

FIG. 3 is a side view schematically illustrating a state where both upper and lower sides of a BP-attached target 10 are pressed through silicon rubber 20 without a spacer 18.

FIG. 4 is a bar graph showing a relationship between a pressing pressure and an amount of warping in Example 1 and Comparative Example 1.

FIG. 5 is a bar graph showing a relationship between a pressing pressure and an amount of warping in Examples 3 to 5 and Comparative Example 2.

FIG. 6 is a side view schematically illustrating a pressed BP-attached target 10 that is reversely warped in Examples 3 to 8.

### DESCRIPTION OF EMBODIMENTS

Hereinafter, a warp correction method for a sputtering target with a backing plate according to the embodiment of the present invention will be described in detail.

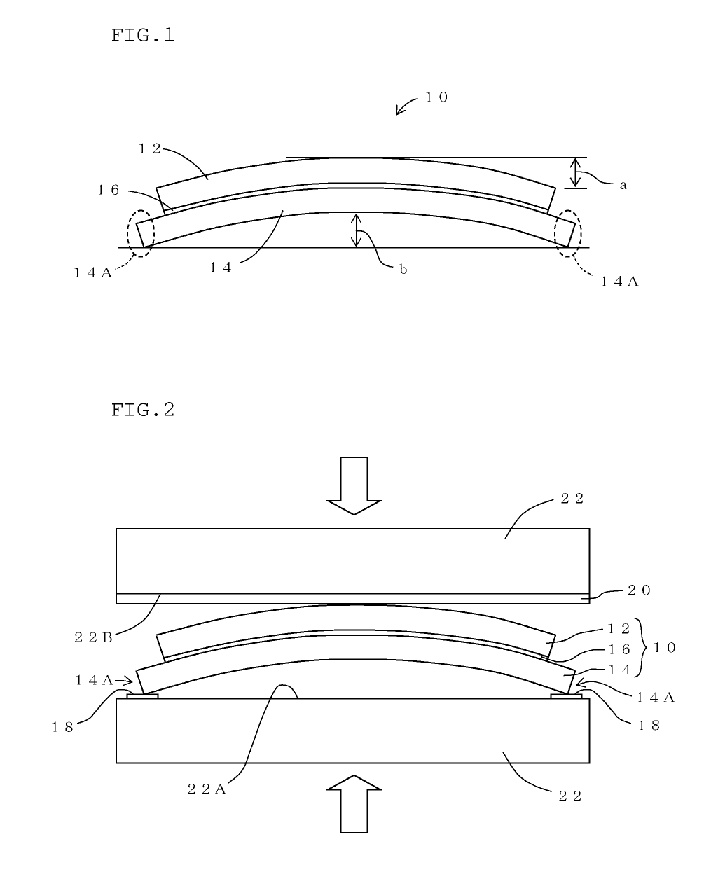

FIG. 1 is a side view schematically illustrating a sputtering target with a backing plate (hereinafter sometimes referred to as “BP-attached target”) that is a subject in which warping is corrected by the warp correction method according to this embodiment.

A sputtering target with a backing plate 10 (hereinafter sometimes referred to as “BP-attached target 10”) includes a sputtering target 12, a backing plate 14, and indium 16. The backing plate 14 is attached to the sputtering target 12 through the indium 16 interposed between the sputtering target 12 and the backing plate 14.

The sputtering target 12 is a composite including metal oxides such as SiO₂, TiO₂, Co₃O₄, and CoO and carbon dispersed in a matrix metal. On the other hand, the backing plate 14 is oxygen-free copper or a copper alloy. For this reason, the thermal expansion coefficient of the backing plate 14 is larger than that of the sputtering target 12.

During attachment of the backing plate 14 to the sputtering target 12, the sputtering target 12 and the backing plate 14 are heated to a temperature at which the indium 16 is molten (for example, about 250 to about 300° C.) to interpose the molten indium 16 between the sputtering target 12 and the backing plate 14, and the indium 16 is cooled to normal temperature and solidified as it is. Thus, the backing plate 14 is attached to the sputtering target 12.

As described above, the thermal expansion coefficient of the backing plate 14 is larger than that of the sputtering target 12. Therefore, when the sputtering target 12 and the backing plate 14 are cooled from the temperature at which the indium 16 is molten (for example, about 250 to about 300° C.) to normal temperature, the shrinkage amount of the backing plate 14 is larger than that of the sputtering target 12. When the backing plate 14 attached to the sputtering target 12 is cooled to normal temperature, the sputtering target 12 side is deformed in a convex shape, and the backing plate 14 side is deformed in a concave shape, as shown in FIG. 1.

In FIG. 1, the amount of warping on the sputtering target 12 side corresponds to a TG warping amount a, and the amount of warping on the backing plate 14 side corresponds to a BP warping amount b. Herein, TG stands for target, and BP stands for backing plate. In Examples described below, a measured BP warping amount b is used as the amount of warping in the BP-attached target.

Hereinafter, a method of correcting warping in the BP-attached target 10 will be specifically described.

FIG. 2 is a side view schematically illustrating a state where the warped BP-attached target 10 is set in a pressing device. Herein, a jig for compression used during pressing constitutes a part of the pressing device.

When warping in the BP-attached target 10 is corrected by the warp correction method according to this embodiment, spacers 18 are first arranged between outer edge 14A of the backing plate 14 side of the BP-attached target 10 and a lower pressing surface 22A of a compressing jig 22 mounted to the pressing device, as shown in FIG. 2. Moreover, silicon rubber 20 is arranged between an outside surface on the sputtering target 12 side of the BP-attached target 10 and an upper pressing surface 22B of the compressing jig 22 mounted to the pressing device.

The BP-attached target 10 is then pressed in the vertical direction by means of the compressing jig 22 mounted to the pressing device, and made flat to decrease warping. The temperature during pressing may be normal temperature, and the atmosphere may be air.

As the pressure to be applied to the BP-attached target 10 is higher, an effect of decreasing warping is enhanced. However, when the pressure to be applied to the BP-attached target 10 is too high, the BP-attached target 10 itself may be damaged by the pressure, and the BP-attached target 10 may be reversely warped by the height of the spacers 18.

Therefore, the pressure to be applied to the BP-attached target 10 is appropriately adjusted according to a state of warping in the BP-attached target 10.

The warp correction method according to this embodiment can be suitably applied to the sputtering target 12 in which the volume fraction of the total of metal oxide and carbon falls within a range of about 10% to about 60% by volume. Even when the volume fraction of the total of metal oxide and carbon is less than 10% by volume, the warp correction method according to this embodiment can be applied. However, when the backing plate 14 is attached to a target in which the volume fraction of the total of metal oxide and carbon is less than 10% by volume, the target is only slightly warped in many cases. When the warp correction method according to this embodiment is applied to small warping, the effect is not markedly exhibited. In contrast, when the volume fraction of the total of metal oxide and carbon is more than 60% by volume, the ratio of metal component in the target decreases, and the target becomes fragile. Thus, when the warp correction method according to this embodiment is implemented, it is necessary that the targeted amount of warping after correction and the targeted pressing pressure be carefully set.

It is preferable that the BP warping amount b that is the amount of warping on the backing plate 14 side of the BP-attached target 10 be less than 0.1 mm after pressing. When the BP warping amount b is decreased to an extent that is less than 0.1 mm, it is difficult to assume that the warped BP-attached target 10 is difficult to be properly mounted to a sputtering device due to warping, and that the BP-attached target 10 is difficult to be properly cooled during sputtering.

When the BP-attached target 10 is pressed as shown in FIG. 2, warping in the BP-attached target 10 can be decreased. The reason is considered, but not clear currently, because when the BP-attached target 10 is pressed as shown in FIG. 2 and made flat, the indium 16 is plastically deformed into the flat shape, and because a force applied to the indium 16 by pressing promotes the plastic deformation of the indium 16. Indium has a melting point as low as 156.6° C. Normal temperature is merely lower than the melting point by about 130° C. Therefore, indium is sufficiently soft at normal temperature, and may be likely to be plastically deformed.

In the warp correction method according to this embodiment, the pressure to be applied to the BP-attached target 10 may be increased to a targeted pressure in a single step or in two steps or more. This will be described again using specific data in Examples.

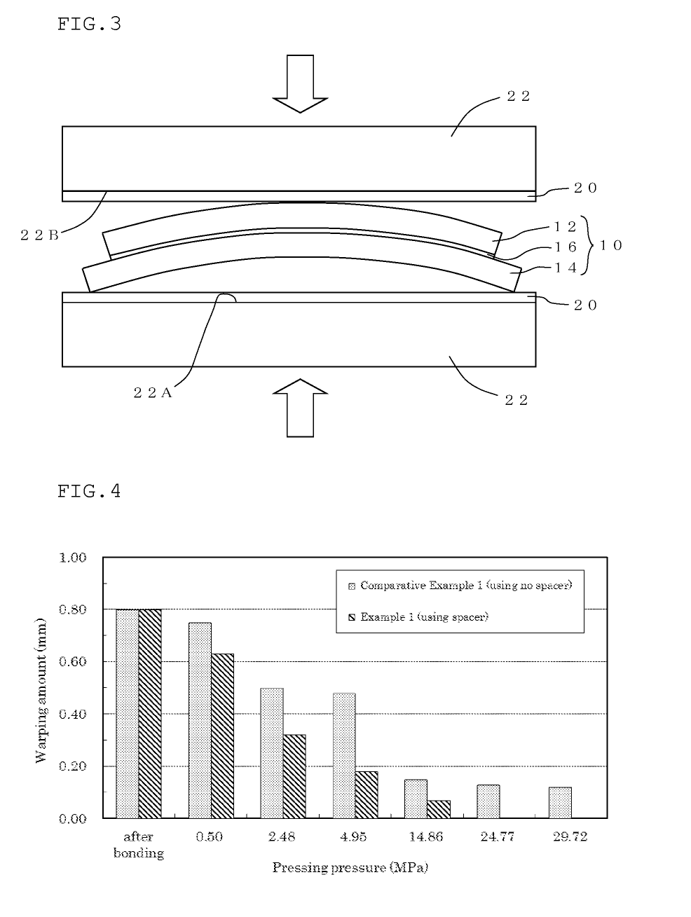

The spacers 18 have a function of enhancing the effect of decreasing warping in the BP-attached target 10 by pressing. As shown in FIG. 3, when the silicon rubber 20 is arranged between the outside surface on the backing plate 14 side of the BP-attached target 10 and the lower pressing surface 22A of the compressing jig 22 mounted to the pressing device, and both the sides of the BP-attached target 10 are pressed through the silicon rubber 20 without the spacers 18, warping in the BP-attached target 10 can be decreased. By pressing using the spacers 18 as shown in this embodiment of FIG. 2, the effect of decreasing warping in the BP-attached target 10 by smaller pressing power as compared with the case shown in FIG. 3 can be effectively exhibited. This will be described again using specific data in Examples.

The thickness of the spacers 18 is preferably 0.05 to 0.5 mm. When the thickness of the spacers 18 is less than 0.05 mm, the function of enhancing the effect of decreasing warping in the BP-attached target 10 by pressing is deteriorated. In contrast, when the thickness of the spacers 18 is more than 0.5 mm, the BP-attached target 10 may be largely reversely warped after pressing. From the viewpoint of securing the function of enhancing the effect of decreasing warping in the BP-attached target 10 by pressing and of a matter wherein the BP-attached target 10 may not be largely reversely warped after pressing, the thickness of the spacers 18 is more preferably 0.07 to 0.4 mm, and particularly preferably 0.08 to 0.2 mm.

It is necessary that the material quality of the spacers 18 be a material quality capable of withstanding a pressure during pressing. However, the material quality is not particularly limited as long as the spacers 18 have characteristics described above. For example, a carbon tool steel material (SK material), SUS304H, or the like can be used as the spacers 18.

The silicon rubber 20 has a function as a buffer material, namely, a function of decreasing concentration of stress on a particular part during compression by pressing the BP-attached target 10 in the vertical direction as shown in FIG. 2, a function of preventing damage of the BP-attached target 10 and the compressing jig 22 that is caused by direct contact between the BP-attached target 10 and the compressing jig 22, and a function of preventing adhesion of dirt to the BP-attached target 10. A material used for the buffer material is not limited to silicon rubber, and may be another material as long as it is a material that has these functions and in which a component does not substantially adhere to the sputtering target 12.

From the viewpoint of relaxing concentration of stress during pressing, the thickness of the silicon rubber 20 is preferably larger. However, when the thickness of the silicon rubber 20 is too large, warping in the BP-attached target 10 may not be sufficiently corrected.

From the viewpoints of relaxing concentration of stress during pressing and of sufficiently correcting warping in the BP-attached target 10, the thickness of the silicon rubber 20 is preferably 0.5 to 1.5 mm, more preferably 0.8 to 1.2 mm, and particularly preferably 0.9 to 1.1 mm.

In the BP-attached target 10 used in this embodiment, indium is used as a brazing filler metal bonding the sputtering target 12 and the backing plate 14. An applicable brazing filler metal is not limited to indium. Any other material may be used as long as it is a material that has excellent plastic deformation capability at normal temperature and a capability of keeping a predetermined shape without flowing even upon application of heat during sputtering. For example, an Sn-based alloy (Sn—Pb alloy, Sn—Ag alloy, Sn—In alloy, Sn—Zn alloy, Sn—Sb alloy, Sn—Pb—Ag alloy, etc.) or another brazing filler metal having low melting point can be used instead of indium. From the viewpoints of plastic deformation capability at normal temperature and shape-keeping capability during sputtering, among Sn-based alloys, an Sn-based alloy having a melting point of 120° C. or higher and 350° C. or lower is preferable. When the melting point is lower than 120° C., the shape-keeping capability during sputtering may be insufficient. When the melting point is higher than 350° C., the plastic deformation capability at normal temperature may be insufficient. From the viewpoints of plastic deformation capability at normal temperature and shape-keeping capability during sputtering, an Sn-based alloy having a melting point of 120° C. or higher and 300° C. or lower is more preferable. From the viewpoints of environmental protection, it is preferable that Pb be not contained.

A material quality of the compressing jig 22 used for pressing is not particularly limited. The material may be a material which has such hardness and strength that substantial deformation and breakage does not occur by a pressure at which the BP-attached target 10 is pressed for correction of warping. For example, stainless, carbon, or the like can be used.

### EXAMPLES

### Example 1

In Example 1, a sputtering target having a diameter of 158.75 mm, a thickness of 3.17 mm, and a composition of Fe-35Pt-15SiO₂-10C (the volume ratios of SiO₂ and C to the whole target were 38.47% and 4.99%, respectively, and the volume ratio of total of SiO₂ and C to the whole target was 43.46% by volume) was used. The sputtering target was a composite including SiO₂ and C dispersed in a matrix metal (FePt alloy).

To the sputtering target, an oxygen-free copper backing plate having a diameter of 165.1 mm and a thickness of 3.18 mm was attached through indium. During attachment through indium, the sputtering target, the oxygen-free copper backing plate, and indium were heated to about 300° C. to interpose molten indium between the sputtering target and the oxygen-free copper backing plate, and the indium was cooled to normal temperature and solidified. Thus, the sputtering target was bonded to the oxygen-free copper backing plate.

In the BP-attached target after cooling to normal temperature and bonding, the amount of warping on the backing plate side (BP warping amount b shown in FIG. 1) was 0.8 mm.

The BP-attached target, spacers, and silicon rubber were arranged in a compressing jig of a pressing device at the same arrangement as in FIG. 2. Specifically, the spacers made of an SK material with a thickness of 0.1 mm were arranged between outer edge of the backing plate side of the BP-attached target and a lower pressing surface of the compressing jig mounted to the pressing device. In addition, the silicon rubber having a thickness of 1.0 mm was arranged between an outside surface on the sputtering target side of the BP-attached target and an upper pressing surface of the compressing jig mounted to the pressing device.

After completion of the arrangement, pressing was performed at normal temperature (about 25° C.) in the air. A pressing pressure to be applied (pressure to be applied) was increased in four steps. Specifically, the pressing pressure was increased in the order of 0.50 MPa, 2.48 MPa, 4.95 MPa, and 14.86 MPa. The pressing pressure at each level was maintained for 10 minutes, the BP-attached target was taken from the pressing device, and the amount of warping on the backing plate side (hereinafter sometimes referred to as “BP warping amount”) was measured. After completion of pressing at a level for 10 minutes, the BP warping amount was measured. After completion of the measurement, the BP-attached target, the spacers, and the silicon rubber were arranged in the compressing jig of the pressing device in the same manner as described above. Then, a pressure at next level was applied, and the BP warping amount was measured. Thus, after the pressure at each level of the four steps was applied for 10 minutes, the BP warping amount was measured each time. The same BP-attached target was subjected to the pressing in the four steps and the measurement of BP warping amount after completion of the pressing at each level.

The results of the measurements in Example 1 are shown in Table 1.

TABLE 1

| Pressing pressure (MPa) | BP warping amount (mm) |
|---|---|
| before pressing | 0.80 |
| 0.50 | 0.63 |
| 2.48 | 0.32 |
| 4.95 | 0.18 |
| 14.86 | 0.07 |

### Comparative Example 1

In Example 1, the spacers were arranged between the outer edge of the backing plate side of the BP-attached target and the lower pressing surface of the compressing jig mounted to the pressing device. In Comparative Example 1, silicon rubber was used instead of the spacers, the silicon rubber was arranged between an outside surface on a backing plate side of a BP-attached target and a lower pressing surface of a compressing jig mounted to a pressing device, and this arrangement was the same as in FIG. 3. Therefore, the BP-attached target was pressed through the silicon rubber from both upper and lower sides.

In Example 1, a pressing pressure was applied in four steps in the order of 0.50 MPa, 2.48 MPa, 4.95 MPa, and 14.86 MPa. In Comparative Example 1, a pressing pressure was applied in six steps in the order of 0.50 MPa, 2.48 MPa, 4.95 MPa, 14.86 MPa, 24.77 MPa, and 29.72 MPa. The pressing pressure at each level was maintained for 10 minutes, the BP-attached target was taken from the pressing device, and the BP warping amount was measured every time after completion of applying the pressing pressure at each level.

An experiment was performed in the same manner as in Example 1 except for above-described points.

The results of the measurements in Comparative Example 1 are shown in Table 2.

TABLE 2

| Pressing pressure (MPa) | BP warping amount (mm) |
|---|---|
| before pressing | 0.80 |
| 0.50 | 0.75 |
| 2.48 | 0.50 |
| 4.95 | 0.48 |
| 14.86 | 0.15 |
| 24.77 | 0.13 |
| 29.72 | 0.12 |

### Consideration of Example 1 and Comparative Example 1

The results of measurement of BP warping amounts in Example 1 and Comparative Example 1 are summarized in Table 3, and are displayed by a bar graph in FIG. 4.

TABLE 3

BP warping amount (mm)

| | | Comparative |
|---|---|---|
| Pressing pressure (MPa) | Example 1 | Example 1 |
| before pressing | 0.80 | 0.80 |
| 0.50 | 0.63 | 0.75 |
| 2.48 | 0.32 | 0.50 |
| 4.95 | 0.18 | 0.48 |
| 14.86 | 0.07 | 0.15 |
| 24.77 | — | 0.13 |
| 29.72 | — | 0.12 |

As shown in Table 3 and FIG. 4, as the pressing pressure is increased in both Example 1 and Comparative Example 1, the BP warping amount is decreased. However, a decrease in the BP warping amount in Example 1 is larger than that in Comparative Example 1.

In Example 1, after pressing at 14.86 MPa, the BP warping amount is 0.07 mm, which is less than 0.1 mm. In Comparative Example 1, even when a pressure up to 29.72 MPa is applied, the BP warping amount is only decreased to 0.12 mm, which is not less than 0.1 mm.

Therefore, the use of the spacers during pressing like Example 1 is considered to be effective in enhancing an effect of decreasing warping in the BP-attached target.

When the BP warping amount is decreased to an extent that is less than 0.1 mm, it is difficult to assume that the BP-attached target is difficult to be properly mounted to a sputtering device, and that the BP-attached target is difficult to be properly cooled during sputtering.

In the BP-attached target before pressing, a state of void present at bonding surfaces of the sputtering target and the backing plate was examined by an ultrasonic defect detection device. Also in the BP-attached target after completion of the pressing (in Example 1, after completion of pressing at 14.86 MPa, and in Comparative Example 1, after completion of pressing at 29.72 MPa), a state of void present at the bonding surfaces of the sputtering target and the backing plate was examined by an ultrasonic defect detection device. The state of void present at the bonding surfaces of the sputtering target and the backing plate was not changed before and after the pressing. It is thus confirmed that the application of pressing pressure within the range that was performed does not adversely influence the bonding surfaces.

After completion of the pressing (in Example 1, after completion of pressing at 14.86 MPa, and in Comparative Example 1, after completion of pressing at 29.72 MPa), the BP-attached target was again heated to about 300° C. to melt indium. Then, the sputtering target was separated from the backing plate. It is confirmed that the sputtering target and the backing plate at that time keep the initial shapes (shapes before bonding through indium). Therefore, it is considered that the sputtering target and the backing plate are not plastically deformed even by pressing like Example 1 and Comparative Example 1. Accordingly, it is considered that the amount of warping in the BP-attached target is decreased by pressing like Example 1 and Comparative Example 1 since indium between the sputtering target and the backing plate is plastically deformed.

The backing plate after the separation keeps the initial shape (shape before bonding through indium) even when pressing is performed like Example 1 and Comparative Example 1. Therefore, when the BP-attached target in which warping is corrected by pressing like Example 1 and Comparative Example 1 is heated after sputtering and the sputtering target is then separated from the backing plate, the separated backing plate can be again used as a backing plate.

### Example 2

In Example 1, a pressing pressure to be applied was increased in four steps in the order of 0.50 MPa, 2.48 MPa, 4.95 MPa, and 14.86 MPa. In Example 2, a pressure of 14.86 MPa was only applied for 10 minutes, that is, pressing was performed in a single step.

An experiment was performed in the same manner as in Example 1 except for above-described point. In Example 2, the BP-attached target corresponding to Example 1 was used.

In Example 2, a pressure of 14.86 MPa was applied for 10 minutes, and the BP warping amount was measured to be 0.07 mm. This BP warping amount was the same as the BP warping amount in Example 1 in which a pressure of 14.86 MPa was applied for 10 minutes. Therefore, if the maximum value of pressing pressure to be finally applied and the time of applying the maximum pressing pressure are substantially the same, even when the pressing pressures gradually increased are applied in steps or the pressing pressure is applied in a single step, the extents of decrease in the BP warping amount are considered to be the same within the range of the experiment.

### Example 3

In Example 3, a sputtering target having a diameter of 153 mm, a thickness of 3 mm, and a composition of 85(Co-40Cr)-15TiO₂ (the volume ratio of TiO₂ to the whole target was 33.02% by volume) was used. The sputtering target was a composite including TiO₂ dispersed in a matrix metal (CoCr alloy).

To the sputtering target, an oxygen-free copper backing plate having a diameter of 161 mm and a thickness of 4 mm was attached through indium. During attachment through indium, the sputtering target, the oxygen-free copper backing plate, and indium were heated to about 300° C. to interpose molten indium between the sputtering target and the oxygen-free copper backing plate, and the indium was cooled to normal temperature and solidified. Thus, the sputtering target was bonded to the oxygen-free copper backing plate.

In the BP-attached target after cooling to normal temperature and bonding, the amount of warping on the backing plate side (BP warping amount b shown in FIG. 1) was 0.23 mm.

The BP-attached target, spacers, and silicon rubber were arranged in a compressing jig of a pressing device at the same arrangement as in FIG. 2. Specifically, the spacers made of an SK material with a thickness of 0.1 mm were arranged between outer edge of the backing plate side of the BP-attached target and a lower pressing surface of the compressing jig mounted to the pressing device. In addition, the silicon rubber having a thickness of 1.0 mm was arranged between an outside surface on the sputtering target side of the BP-attached target and an upper pressing surface of the compressing jig mounted to the pressing device.

After completion of the arrangement, pressing was performed at normal temperature (about 25° C.) in the air. A pressing pressure to be applied (pressure to be applied) was increased in two steps. Specifically, the pressing pressure was increased in the order of 0.53 MPa and 2.67 MPa. The pressing pressure at each level was maintained for 10 minutes, the BP-attached target was taken from the pressing device, and the amount of warping on the backing plate side (BP warping amount) was measured. After completion of pressing at a level for 10 minutes, the BP warping amount was measured. After completion of the measurement, the BP-attached target, the spacers, and the silicon rubber were arranged in the compressing jig of the pressing device in the same manner as described above. Then, a pressure at next level was applied, and the BP warping amount was measured. Thus, after the pressure at each level of the two steps was applied for 10 minutes, the BP warping amount was measured each time. The same BP-attached target was subjected to the pressing in the two steps and the measurement of BP warping amount after completion of the pressing at each level.

The results of the measurements in Example 3 are shown in Table 4.

TABLE 4

| Pressing pressure (MPa) | BP warping amount (mm) |
|---|---|
| before pressing | 0.23 |
| 0.53 | 0.06 |
| 2.67 | 0.01 |

### Example 4

In Example 3, a spacer having a thickness of 0.1 mm was used. In Example 4, a spacer having a thickness of 0.2 mm was used.

An experiment was performed in the same manner as in Example 3 except for above-described point. Although a BP-attached target corresponding to Example 3 was used in Example 4, the BP warping amount before pressing in the BP-attached target used in Example 4 was 0.24 mm.

The results of the measurements in Example 4 are shown in Table 5.

TABLE 5

| Pressing pressure (MPa) | BP warping amount (mm) |
|---|---|
| before pressing | 0.24 |
| 0.53 | 0.05 |
| 2.67 | 0.01 |

### Example 5

In Example 3, a spacer having a thickness of 0.1 mm was used. In Example 5, a spacer having a thickness of 0.3 mm was used.

An experiment was performed in the same manner as in Example 3 except for above-described point. Although a BP-attached target corresponding to Example 3 was used in Example 5, the BP warping amount before pressing in the BP-attached target used in Example 5 was 0.25 mm.

The results of the measurements in Example 5 are shown in Table 6.

TABLE 6

| Pressing pressure (MPa) | BP warping amount (mm) |
|---|---|
| before pressing | 0.25 |
| 0.53 | 0.05 |
| 2.67 | 0.01 |

### Comparative Example 2

In Example 3, the spacers were arranged between the outer edge of the backing plate side of the BP-attached target and the lower pressing surface of the compressing jig mounted to the pressing device. In Comparative Example 2, silicon rubber was used instead of the spacers, the silicon rubber was arranged between an outside surface on a backing plate side of a BP-attached target and a lower pressing surface of a compressing jig mounted to a pressing device, and this arrangement was the same as in FIG. 3. Therefore, the BP-attached target was pressed through the silicon rubber from both upper and lower sides.

In Example 3, a pressing pressure was applied in two steps in the order of 0.53 MPa and 2.67 MPa. In Comparative Example 2, a pressing pressure was applied in six steps in the order of 0.53 MPa, 2.67 MPa, 5.33 MPa, 16.00 MPa, 26.67 MPa, and 29.33 MPa. The pressing pressure at each level was maintained for 10 minutes, the BP-attached target was taken from the pressing device, and the BP warping amount was measured every time after completion of applying the pressing pressure at each level.

An experiment was performed in the same manner as in Example 3 except for above-described points.

The results of the measurements in Comparative Example 2 are shown in Table 7.

TABLE 7

| Pressing pressure (MPa) | BP warping amount (mm) |
|---|---|
| before pressing | 0.25 |
| 0.53 | 0.15 |
| 2.67 | 0.09 |
| 5.33 | 0.08 |
| 16.00 | 0.05 |
| 26.67 | 0.04 |
| 29.33 | 0.02 |

### Consideration of Examples 3 to 5 and Comparative Example 2

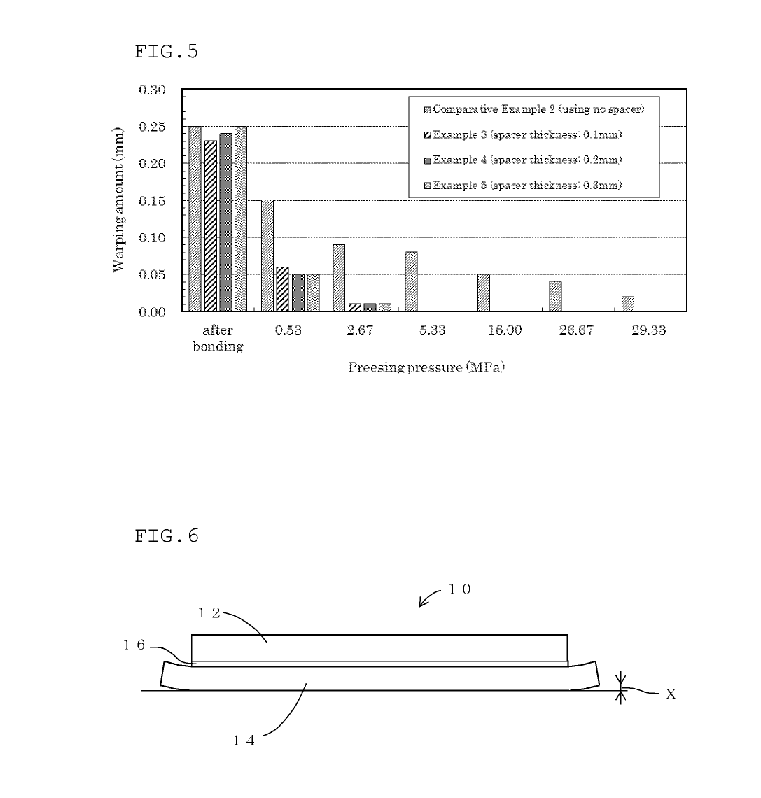

The results of measurement of BP warping amounts in Examples 3 to 5 and Comparative Example 2 are summarized in Table 8, and are displayed by a bar graph in FIG. 5. Note that in Table 8, the BP warping amounts at pressing pressures of 5.33 MPa, 16.00 MPa, 26.67 MPa, and 29.33 MPa, which were measured in Comparative Example 2, are not described for the sake of formation of Table. In FIG. 5, the BP warping amounts at the pressing pressures are displayed by a bar graph.

TABLE 8

| | | BP warping amount (mm) | | |
|---|---|---|---|---|
| | Spacer | | Pressing | Pressing |
| | thickness | before | pressure: | pressure: |
| | (mm) | pressing | 0.53 MPa | 2.67 MPa |
| Example 3 | 0.1 | 0.23 | 0.06 | 0.01 |
| Example 4 | 0.2 | 0.24 | 0.05 | 0.01 |
| Example 5 | 0.3 | 0.25 | 0.05 | 0.01 |
| Comparative | Using | 0.25 | 0.15 | 0.09 |
| Example 2 | no spacer | | | |

As shown in Table 8 and FIG. 5, as the pressing pressure is increased, the BP warping amount is decreased in all Examples 3 to 5 and Comparative Example 2. However, a decrease in the BP warping amount in Examples 3 to 5 is larger than that in Comparative Example 2.

In Examples 3, 4, and 5, after pressing at 0.53 MPa, the BP warping amount is 0.06 mm, 0.05 mm, and 0.05 mm, respectively, which are less than 0.1 mm. In Comparative Example 2, by pressing at 0.53 MPa, the BP warping amount is only decreased to 0.15 mm, which is not less than 0.1 mm.

Therefore, the use of the spacers during pressing like Examples 3 to 5 is considered to be effective in enhancing an effect of decreasing warping in the BP-attached target.

When the BP warping amount is decreased to an extent that is less than 0.1 mm, it is difficult to assume that the BP-attached target is difficult to be properly mounted to a sputtering device, and that the BP-attached target is difficult to be properly cooled during sputtering.

The thickness of the spacers used is 0.1 mm in Example 3, 0.2 mm in Example 4, and 0.3 mm in Example 5. The BP warping amounts in Examples 3, 4, and 5 after applying a pressing pressure of 0.53 MPa are 0.06 mm, 0.05 mm, and 0.05 mm, respectively, and have almost no difference. All the BP warping amounts in Examples 3, 4, and 5 after applying a pressing pressure of 2.67 MPa are 0.01 mm, and have no difference. Therefore, even when the thickness of the spacers is varied within a range of 0.1 to 0.3 mm, the effect of reducing the BP warping amount is considered to be hardly affected.

In the BP-attached target before pressing, a state of void present at bonding surfaces of the sputtering target and the backing plate was examined by an ultrasonic defect detection device. Also in the BP-attached target after completion of the pressing (in Examples 3 to 5 and Comparative Example 2, after completion of pressing at 2.67 MPa), a state of void present at the bonding surfaces of the sputtering target and the backing plate was examined by an ultrasonic defect detection device. The state of void present at the bonding surfaces of the sputtering target and the backing plate was not changed before and after the pressing. It is confirmed that the application of pressing pressure within the range that was performed does not adversely influence the bonding surfaces.

After completion of the pressing (in Examples 3 to 5, after completion of pressing at 2.67 MPa, and in Comparative Example 2, after completion of pressing at 29.33 MPa), the BP-attached target was again heated to about 300° C. to melt indium. Then, the sputtering target was separated from the backing plate. It is confirmed that the sputtering target and the backing plate at that time keep the initial shapes (shapes before bonding through indium). Therefore, it is considered that the sputtering target and the backing plate are not plastically deformed even by pressing like Examples 3 to 5 and Comparative Example 2. Accordingly, it is considered that the amount of warping in the BP-attached target is decreased by pressing like Examples 3 to 5 and Comparative Example 2 since indium between the sputtering target and the backing plate is plastically deformed.

The backing plate after the separation keeps the initial shape (shape before bonding through indium) even when pressing is performed like Examples 3 to 5 and Comparative Example 2. Therefore, when the BP-attached target in which warping is corrected by pressing like Examples 3 to 5 and Comparative Example 2 is heated after sputtering and the sputtering target is then separated from the backing plate, the separated backing plate can be again used as a backing plate.

### Example 6

In Example 3, a pressing pressure to be applied was increased in two steps in the order of 0.53 MPa and 2.67 MPa. In Example 6, a pressure of 2.51 MPa was only applied for 10 minutes, that is, pressing was performed in a single step.

An experiment was performed in the same manner as in Example 3 except for above-described point. A spacer having a thickness of 0.1 mm was used. In Example 6, the BP-attached target corresponding to Example 3 was used.

In Example 6, a pressure of 2.51 MPa was applied for 10 minutes, and the BP warping amount was measured to be 0.01 mm. This BP warping amount was the same as the BP warping amount in Example 3 in which a pressure of 2.67 MPa was applied for 10 minutes. Therefore, if the maximum value of pressing pressure to be finally applied and the time of applying the maximum pressing pressure are substantially the same, even when the pressing pressures gradually increased are applied in steps or the pressing pressure is applied in a single step, the extents of decrease in the BP warping amount are considered to be the same.

### Example 7

In Example 4, a pressing pressure to be applied was increased in two steps in the order of 0.53 MPa and 2.67 MPa. In Example 7, a pressure of 2.51 MPa was only applied for 10 minutes, that is, pressing was performed in a single step.

An experiment was performed in the same manner as in Example 4 except for above-described point. A spacer having a thickness of 0.2 mm was used. In Example 7, the BP-attached target corresponding to Example 4 was used.

In Example 7, a pressure of 2.51 MPa was applied for 10 minutes, and the BP warping amount was measured to be 0.01 mm. This BP warping amount was the same as the BP warping amount in Example 4 in which a pressure of 2.67 MPa was applied for 10 minutes. Therefore, if the maximum value of pressing pressure to be finally applied and the time of applying the maximum pressing pressure are substantially the same, even when the pressing pressures gradually increased are applied in steps or the pressing pressure is applied in a single step, the extents of decrease in the BP warping amount are considered to be the same.

### Example 8

In Example 5, a pressing pressure to be applied was increased in two steps in the order of 0.53 MPa and 2.67 MPa. In Example 8, a pressure of 2.51 MPa was only applied for 10 minutes, that is, pressing was performed in a single step.

An experiment was performed in the same manner as in Example 5 except for above-described point. A spacer having a thickness of 0.3 mm was used. In Example 8, the BP-attached target corresponding to Example 5 was used.

In Example 8, a pressure of 2.51 MPa was applied for 10 minutes, and the BP warping amount was measured to be 0.01 mm. This BP warping amount was the same as the BP warping amount in Example 5 in which a pressure of 2.67 MPa was applied for 10 minutes. Therefore, if the maximum value of pressing pressure to be finally applied and the time of applying the maximum pressing pressure are substantially the same, even when the pressing pressures gradually increased are applied in steps or the pressing pressure is applied in a single step, the extents of decrease in the BP warping amount are considered to be the same.

### Reverse Warping in Examples 3 to 8

In Examples 3 to 5 in which pressing was performed in two steps, after completion of pressing at 2.67 MPa, the outer edges of the backing plate were observed. The backing plate was reversely warped (warped in a direction opposite to the warping before pressing) as shown in FIG. 6. Also in Examples 6 to 8 in which pressing was performed in a single step, after completion of pressing at 2.51 MPa, the outer edges of the backing plate were observed. The backing plate was reversely warped (warped in a direction opposite to the warping before pressing) as shown in FIG. 6.

In FIG. 6, an amount of reverse warping X represents the amount of reverse warping in the outer edge of the backing plate 14.

The reverse warping observed in the backing plate after completion of pressing in Examples 3 to 8 was observed only at the outer edges of the backing plate. The backing plate was flat around a central region.

The amounts of reverse warping observed in the backing plate after completion of pressing at 2.67 MPa in Examples 3 to 5 and after completion of pressing at 2.51 MPa in Examples 6 to 8 are summarized in Table 9.

TABLE 9

| | Spacer | | Reverse |
|---|---|---|---|
| | thickness | | warping amount |
| | (mm) | Pressing method | (mm) |
| Example 3 | 0.1 | Pressing in two steps | 0.02 |
| | | (0.53 MPa, 2.67 MPa) | |
| Example 4 | 0.2 | Pressing in two steps | 0.03 |
| | | (0.53 MPa, 2.67 MPa) | |
| Example 5 | 0.3 | Pressing in two steps | 0.05 |
| | | (0.53 MPa, 2.67 MPa) | |
| Example 6 | 0.1 | Pressing in a single | 0.01 |
| | | Step (2.51 MPa) | |
| Example 7 | 0.2 | Pressing in a single | 0.03 |
| | | Step (2.51 MPa) | |
| Example 8 | 0.3 | Pressing in a single | 0.06 |
| | | Step (2.51 MPa) | |

As shown in Table 9, as the thickness of the spacers is larger, the amount of reverse warping is larger. Therefore, it is considered that the thickness of the spacers is preferably thinner within the range of the experiment. However, in Examples 5 and 8 in which the thickness of the spacers was 0.3 mm, the amount of reverse warping is 0.05 mm and 0.06 mm, respectively, which are less than 0.1 mm. Thus, it is difficult to assume that the BP-attached target is difficult to be properly mounted to a sputtering device, and that the BP-attached target is difficult to be properly cooled during sputtering.

After completion of pressing at 2.67 MPa in Examples 3 to 5 and after completion of pressing at 2.51 MPa in Examples 6 to 8, the BP-attached target was heated to about 300° C. to melt indium. Then, the sputtering target was separated from the backing plate. It is confirmed that the sputtering target and the backing plate at that time keep the initial shapes (shapes before bonding through indium). It is considered that the backing plate is not plastically deformed by the reverse warping. Therefore, the reverse warping is considered not to be an obstacle for reuse of the backing plate.

In Examples 3 and 6 using the spacers having a thickness of 0.1 mm, the amounts of reverse warping are 0.02 mm and 0.01 mm, respectively. In Examples 4 and 7 using the spacers having a thickness of 0.2 mm, the amounts of reverse warping are 0.03 mm and 0.03 mm, respectively. In Examples 5 and 8 using the spacers having a thickness of 0.3 mm, the amounts of reverse warping are 0.05 mm and 0.06 mm, respectively. Therefore, if the thicknesses of the spacers to be used are the same and the maximum values of pressing pressures to be finally applied and the times of applying the maximum pressing pressure are substantially the same, even when the pressing pressures gradually increased are applied in steps or the pressing pressure is applied in a single step, effects on occurrence of reverse warping are considered to have no substantial difference.

In Comparative Example 2 using no spacer, even when a pressing pressure up to 29.33 MPa was applied, reverse warping was not caused.

### Example 9

In Example 9, a sputtering target having a diameter of 161.93 mm, a thickness of 3.18 mm, and a composition of 89(Co-10Cr-18Pt)-5TiO₂-3Co₃O₄-3B₂O₃ was used. The sputtering target was a composite including oxides (TiO₂, Co₃O₄, and B₂O₃) dispersed in a matrix metal (CoCrPt alloy). The volume ratio of the total of the oxides (TiO₂, Co₃O₄, and B₂O₃) to the whole target was 34.08% by volume.

To the sputtering target, a stepped oxygen-free copper backing plate was attached through indium. The outer diameters of this stepped oxygen-free copper backing plate on sides closer to and apart from the target are different, the shape on the side closer to the target (on the side bonded to the target) has a diameter of 161.93 mm and a thickness of 1.50 mm, the shape on the side apart from the target has a diameter of 165.10 mm and a thickness of 1.68 mm, and the total thickness is 3.18 mm. Hereinafter, these will be described with reference to FIGS. 1, 2, and 6. The outer diameters of the stepped oxygen-free copper backing plate used in Example 9 on sides closer to and apart from the target are different as described above, and the shape thereof is different from the shapes of the backing plates 14 in FIGS. 1, 2, and 6.

In Example 9, when the sputtering target was attached to the stepped oxygen-free copper backing plate through indium, the sputtering target, the stepped oxygen-free copper backing plate, and indium were heated to about 300° C. to interpose molten indium between the sputtering target and the stepped oxygen-free copper backing plate, and the indium was cooled to normal temperature and solidified. Thus, the sputtering target was bonded to the stepped oxygen-free backing plate.

In the BP-attached target after cooling to normal temperature and bonding, the amount of warping on the backing plate side (BP warping amount b shown in FIG. 1) was 0.32 mm.

The BP-attached target, spacers, and silicon rubber were arranged in a compressing jig of a pressing device at the same arrangement as in FIG. 2. Specifically, the spacers made of an SK material with a thickness of 0.1 mm were arranged between outer edge of the backing plate side of the BP-attached target and a lower pressing surface of the compressing jig mounted to the pressing device. In addition, the silicon rubber having a thickness of 1.0 mm was arranged between an outside surface on the sputtering target side of the BP-attached target and an upper pressing surface of the compressing jig mounted to the pressing device.

After completion of the arrangement, the BP-attached target in which the sputtering target was bonded to the stepped oxygen-free copper backing plate through indium was pressed at normal temperature (about 25° C.) in the air. In Example 9, a pressure of 2.67 MPa was only applied for 10 minutes, that is, pressing was performed in a single step. After completion of the pressing, the BP-attached target was taken from the pressing device, and the amount of warping on the backing plate side (BP warping amount) was measured to be 0.02 mm. This amount was a BP warping amount sufficiently less than 0.1 mm.

In Example 9 in which pressing was performed in a single step, after completion of pressing at 2.67 MPa, the outer edge of the backing plate were observed. The backing plate was reversely warped (warped in a direction opposite to the warping before pressing) as shown in FIG. 6. In FIG. 6, an amount of reverse warping X represents the amount of reverse warping in the outer edge of the backing plate 14. The amount of reverse warping observed in the backing plate after completion of pressing at 2.67 MPa in Example 9 was measured to be 0.01 mm. This amount was a reverse warping amount sufficiently less than 0.1 mm.

### Example 10

In Example 10, a sputtering target having a diameter of 161.93 mm, a thickness of 3.18 mm, and a composition of 90 (Co-15Cr-20Pt)-4SiO₂-3TiO₂-3CoO was used. The sputtering target was a composite including oxides (SiO₂, TiO₂, and CoO) dispersed in a matrix metal (CoCrPt alloy). The volume ratio of the total of the oxides (SiO₂, TiO₂, and CoO) to the whole target was 23.72% by volume.

An experiment was performed in the same manner as in Example 9 except for above-described point.

In the BP-attached target in which the sputtering target was bonded to the stepped oxygen-free copper backing plate through indium, the amount of warping on the backing plate side (BP warping amount b shown in FIG. 1) was 0.28 mm.

The BP-attached target in which the sputtering target was bonded to the stepped oxygen-free copper backing plate through indium was pressed at 2.67 MPa for 10 minutes in a single step in the same manner as in Example 9. The amount of warping on the pressed backing plate side (BP warping amount) was measured to be 0.01 mm. This amount was a BP warping amount sufficiently less than 0.1 mm.

In Example 10 in which pressing was performed in a single step, after completion of pressing at 2.67 MPa, the outer edge of the backing plate were observed. The backing plate was reversely warped (warped in a direction opposite to the warping before pressing) as shown in FIG. 6. In FIG. 6, an amount of reverse warping X represents the amount of reverse warping in the outer edge of the backing plate 14. The amount of reverse warping observed in the backing plate after completion of pressing at 2.67 MPa in Example 10 was 0.01 mm. This amount was a reverse warping amount sufficiently less than 0.1 mm.

### INDUSTRIAL APPLICABILITY

According to the present invention, warping in a warped sputtering target with a backing plate can be corrected by a simple method.

### REFERENCE SIGNS LIST

10 sputtering target with a backing plate (BP-attached target)
12 sputtering target
14 backing plate
14A outer edge
16 indium
18 spacer
20 silicon rubber
22 pressing device
22A lower pressing surface
22B upper pressing surface
a TG warping amount
b BP warping amount
X amount of reverse warping

1. A warp correction method for a sputtering target with a backing plate, the method being for decreasing warping in the sputtering target with the backing plate, the sputtering target being bonded to the backing plate through a brazing filler metal, the sputtering target with the backing plate being warped convexly on the sputtering target side and being warped concavely on the backing plate side, the method comprising:
an arrangement step of arranging the sputtering target with the backing plate on a lower pressing surface of a pressing device in such a way that the sputtering target side located above, the pressing device including an upper pressing surface and the lower pressing surface opposing each other in a vertical direction, the pressing device being capable of pressing a substance to be pressed arranged on the lower pressing surface in the vertical direction, and of arranging a spacer between outer edge of the backing plate side of the sputtering target with the backing plate and the lower pressing surface of the pressing device; and
a pressing step of pressing the sputtering target with the backing plate in the vertical direction by means of the pressing device after the arrangement step,
wherein the sputtering target is a composite including at least one of metal oxide and carbon, the at least one of metal oxide and carbon being dispersed in a matrix metal.

2. The warp correction method for a sputtering target with a backing plate according to claim 1,
wherein a volume fraction of a total of the metal oxide and the carbon relative to the whole sputtering target is 10 to 60% by volume.

3. The warp correction method for a sputtering target with a backing plate according to claim 1,
wherein the backing plate is oxygen-free copper or a copper alloy.

4. The warp correction method for a sputtering target with a backing plate according to claim 1,
wherein in the pressing step, a pressure to be applied to the sputtering target with the backing plate is increased to a targeted pressure in a single step.

5. The warp correction method for a sputtering target with a backing plate according to claim 1,
wherein an amount of warping on the backing plate side of less than 0.1 mm is achieved.

6. The warp correction method for a sputtering target with a backing plate according to claim 1,
wherein the spacer has a thickness of 0.05 to 0.5 mm.

7. The warp correction method for a sputtering target with a backing plate according to claim 1,
wherein the brazing filler metal is indium.

8. The warp correction method for a sputtering target with a backing plate according to claim 1,
wherein the brazing filler metal is an Sn-based alloy.

9. The warp correction method for a sputtering target with a backing plate according to claim 1,
wherein in the arrangement step, a buffer material is arranged between an outside surface of the sputtering target with the backing plate on the sputtering target side and the upper pressing surface.

10. The warp correction method for a sputtering target with a backing plate according to claim 9,
wherein the buffer material is silicon rubber.

11. The warp correction method for a sputtering target with a backing plate according to claim 10,
wherein the silicon rubber has a thickness of 0.5 to 1.5 mm.

12. The warp correction method for a sputtering target with a backing plate according to claim 1,
wherein the method is performed at normal temperature in the air.

13. The warp correction method for a sputtering target with a backing plate according to claim 1,
wherein the method is performed so that the sputtering target and the backing plate are not plastically deformed.

14. The warp correction method for a sputtering target with a backing plate according to claim 2.
wherein the backing plate is oxygen-free copper or a copper alloy.

15. The warp correction method for a sputtering target with a backing plate according to claim 2,
wherein in the pressing step, a pressure to be applied to the sputtering target with the backing plate is increased to a targeted pressure in a single step.

16. The warp correction method for a sputtering target with a backing plate according to claim 3,
wherein in the pressing step, a pressure to be applied to the sputtering target with the backing plate is increased to a targeted pressure in a single step.

17. The warp correction method for a sputtering target with a backing plate according to claim 2,
wherein the method is performed at normal temperature in the air.

18. The warp correction method for a sputtering target with a backing plate according to claim 3,
wherein the method is performed at normal temperature in the air.

19. The warp correction method for a sputtering target with a backing plate according to claim 4,
wherein the method is performed at normal temperature in the air.

20. The warp correction method for a sputtering target with a backing plate according to claim 2,
wherein the spacer has a thickness of 0.05 to 0.5 mm.
